(19) United States
(12) Patent Application Publication
(10) Pub. No.: US 2013/0140597 A1
(43) Pub. Date: Jun. 6, 2013

(54) Organic Light Emitting Device and Manufacturing Method Thereof

(71) Applicant: SAMSUNG DISPLAY CO., LTD., Yongin-City (KR)

(72) Inventors: Nam-Jin Kim, Suwon-si (KR); Chul-Hwan Park, Asan-si (KR)

(73) Assignee: SAMSUNG DISPLAY CO., LTD., Yongin-City (KR)

(21) Appl. No.: 13/624,556

(22) Filed: Sep. 21, 2012

(30) Foreign Application Priority Data
Dec. 6, 2011 (KR) 10-2011-0129388

(51) Int. Cl. H01L 51/50; H01L 51/56

(52) U.S. Cl. 257/98; 438/29; 257/E51.026

(57) ABSTRACT

In an organic light emitting device and a method of manufacturing the organic light emitting device, reflective layers are formed on pixel definition layers to prevent the generation of an open edge defect (or a non-transfer defect) in forming light emitting layers. The organic light emitting device includes a base, first electrodes patterned and formed on the base, light emitting layers formed on the first electrodes, and a second electrode formed on the light emitting layers. Pixel definition layers are formed between the patterned first electrodes, and reflective layers are disposed in the pixel definition layers.

### CLAIM OF PRIORITY

This application makes reference to, incorporates the same herein, and claims all benefits accruing under 35 U.S.C. §119 from an application for ORGANIC LIGHT EMITTING DEVICE AND MANUFACTURING METHOD THEREOF earlier filed in the Korean Intellectual Property Office on 6 Dec. 2011 and there duly assigned Serial No. 10-2011-0129388.

### BACKGROUND OF THE INVENTION

1. Field of the Invention

The present invention relates to an organic light emitting device and a method of manufacturing the organic light emitting device, and more particularly to an organic light emitting device and a method of manufacturing the organic light emitting device, in which reflective layers are formed on pixel definition layers, thereby preventing the generation of a non-transfer defect during formation of light emitting layers.

2. Description of the Related Art

In recent years, organic light emitting devices are being spotlighted in the field of display technology. Such an organic light emitting device is a device using light generated when electrons and holes are combined and dissipate while emitting the light.

The organic light emitting device basically includes an electrode for injecting holes, an electrode for injecting electrons, and a light emitting layer, and the device has a lamination structure in which the light emitting layer is interposed between an anode that is the electrode for injecting the holes and a cathode that is the electrode for injecting the electrons. Particularly, among the electrodes of the organic light emitting device, the electrons are injected in the cathode, the holes are injected in the anode, and these charges are moved to each other in counter directions by an external electric field and are then combined in the light emitting layer, so that they dissipate while emitting light. The light emitting layer of the organic light emitting device is formed of a single molecule organic material or a polymer.

The organic light emitting device generally includes pixel definition layers (PDLs) for covering an edge of the anode. Furthermore, a light emitting layer among the organic thin films is formed in a partial region of the pixel definition layer.

A method of patterning the light emitting layer includes a method using a shadow mask for a low molecular organic light emitting device, and ink-jet printing or laser induced thermal imaging (LITI) for a polymer organic light emitting device.

In order to form the light emitting layer by a donor film including an organic layer is first laminated on a substrate. Then, when a laser is irradiated onto a predetermined part of the donor film, a patterned light emitting layer may be on the substrate. That is, a combination between a part to which the laser is irradiated and a part to which the laser is not irradiated is disconnected in the organic layer of the donor film, so that the pattern of the light emitting layer may be formed.

However, when a transfer is performed through an irradiation of the laser in a state in which a donor film is aligned with a pixel part, an open edge defect may be generated, in which a portion in an edge part may not be transferred due to a continuous application of a forte between a portion that has been irradiated by the laser and a portion that has not been irradiated by the laser.

Accordingly, technology capable of preventing the open edge defect generated due to the failure of appropriate contact between an end of the anode and the light emitting layer when the light emitting layer is patterned through the LITI is required.

### SUMMARY OF THE INVENTION

The present invention has been developed to solve the above-mentioned problems occurring in the prior art, and an aspect of the present invention provides an organic light emitting device with an improved durability and a method of manufacturing the organic light emitting device in which the generation of the non-transfer defect is prevented during the forming of light emitting layers.

According to an exemplary embodiment of the present invention, there is provided an organic light emitting device including a base, first electrodes patterned and formed on the base, light emitting layers formed on the first electrodes, and a second electrode formed on the light emitting layers, wherein pixel definition layers are formed between the patterned fast electrodes and reflective layers are disposed in the pixel definition layers.

The light emitting layer is formed of a monomer or a polymer organic material.

According to an exemplary embodiment of the present invention, the reflective layer is formed on an upper portion of the pixel definition layer and an area of the reflective layer is 50% to 100% of that of an upper portion of the pixel definition layer.

According to an exemplary embodiment of the present invention, the reflective layer is formed in an interior of the pixel definition layer, and more particularly on the substrate. In the present exemplary embodiment, a case where the reflective layer is directly in contact with the substrate is described, but a third layer may be disposed between the reflective layer and the substrate.

Meanwhile, the area of the reflective layer is 50% to 90% of that of a lower portion of the pixel definition layer, and an outside portion of the reflective layer is covered by the pixel definition layer.

According to an exemplary embodiment of the present invention, the organic light emitting device further includes at least one of a hole injection layer and a hole transport layer between the light emitting layer and the first electrode.

According to another exemplary embodiment of the present invention, the organic light emitting device further includes at least one of an electron injection layer and an electron transport layer between the light emitting layer and the second electrode.

According to an exemplary embodiment of the present invention, the first electrode may be a pixel electrode. Furthermore, the second electrode may be a common electrode. In this case, the second electrode is formed over upper portions of the pixel definition layers and the reflective layers, as well as upper portions of the light emitting layers.

According to an exemplary embodiment of the present invention, the first electrode is an anode and the second electrode is a cathode. A terminal having a lower voltage than that of the first electrode may be the second electrode. That is, the second electrode is the cathode.

According to an exemplary embodiment of the present invention, the reflective layer includes a metal layer. The metal layer includes at least one of a molybdenum (Mo) layer, a gold (Au) layer, a silver (Ag) layer, a chrome (Cr) layer, a titanium (Ti) layer, a ytterbium (Yb) layer, a copper (Cu) layer, and an aluminum (Al) layer.

According to an exemplary embodiment of the present invention, the reflective layers are formed in any one of a form of a mesh, lines, and a comb.

According to an exemplary embodiment of the present invention, the base may include a substrate, a thin film transistor (TFT) layer, and a flat insulation layer. Furthermore, the base may be only a substrate.

Furthermore, the present invention provides a method of manufacturing the organic light emitting device.

The method of manufacturing the organic light emitting device according to the present invention includes the steps of preparing a base, forming patterns of first electrodes on the base, forming pixel definition layers between the patterned first electrodes such that the first electrodes are classified in units of pixels, forming light emitting layers on the first electrodes classified in units of pixels, and forming a second electrode on the light emitting layers, wherein a step of forming reflective layers is included before or after the step of forming the pixel definition layers.

According to an exemplary embodiment of the present invention, the step of forming the reflective layers is performed after the step of forming the pixel definition layers, and the reflective layers are formed on the pixel definition layers.

According to another exemplary embodiment of the present invention, the step of forming the reflective layers is performed before the step of forming the pixel definition layers, and the pixel definition layers are formed on the reflective layers.

According to another exemplary embodiment of the present invention, the step of forming the reflective layers is performed simultaneously with the step of forming the patterns of the first electrodes.

According to an exemplary embodiment of the present invention, the method further includes at least one of a step of forming a hole injection layer and a step of forming a hole transport layer after the step of forming the pixel definition layers and before the step of forming the light emitting layers.

According to an exemplary embodiment of the present invention, the method further includes at least one of a step of forming an electron transport layer and a step of forming an electron injection layer after the step of forming the light emitting layers and before the step of forming the second electrode.

According to an exemplary embodiment of the present invention, the step of forming the reflective layers may include a step of forming metal layers. The metal layers may be formed of at least one of a molybdenum (Mo) layer, a gold (Au) layer, a silver (Ag) layer, a chrome (Cr) layer, a titanium (Ti) layer, a ytterbium (Yb) layer, a copper (Cu) layer, and an aluminum (Al) layer.

According to an exemplary embodiment of the present invention, in the step of forming the reflective layers, the reflective layers are formed in any one of a form of a mesh, lines, and a comb.

Accordingly, in the organic light emitting device according to the present invention, the reflective layers are formed in the pixel definition layers, and it is possible to prevent the transfer defect, such as the non-transfer of the edge portion of the electrode, when the transfer is performed through laser irradiation, thereby advantageously improving a pattern image characteristic at the edge portion of the electrode.

Furthermore, according to the method of manufacturing the organic light emitting device of the present invention, the step of forming the first electrodes and the step of forming the reflective layers are simultaneously performed, so that it is possible to manufacture an organic light emitting device in which the non-transfer defect is prevented without an additional mask or adding a complicated process.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic view illustrating a general transfer process of an organic light emitting device;

FIG. 2 is a view illustrating an example of a non-transfer defect generated due to the continuous application of a three between in a region that has been irradiated by the laser and a region that has not been irradiated by the laser when a transfer is performed;

FIG. 3 is a view illustrating an organic light emitting device according to an embodiment of the present invention;

FIG. 4 is a view illustrating exemplary planar dispositions of reflective layers in an organic light emitting device according to the present invention;

FIG. 5 is a view illustrating a transfer process of an organic light emitting device according to an embodiment of the present invention;

FIG. 6 is a view illustrating an organic light emitting device according to another embodiment of the present invention; and

FIG. 7 is a view illustrating a transfer process of an organic light emitting device according to another embodiment of the present invention.

### DETAILED DESCRIPTION OF THE INVENTION

Hereinafter, exemplary embodiments of the present invention will be described with reference to the accompanying drawings. However, it should be noted that the scope of the present invention is not limited by the below-described embodiments and the drawings. Furthermore, it will be understood that all changes, equivalents, or substitutes included in the spirit and technical scope of the present invention are included in the scope of the present invention.

Although terms used herein are selected from widely used general terms as often as possible, several terms were selected by the applicant of the present invention depending on particular circumstances, and in this case the meaning of the terms selected by the applicant should be understood considering a meaning described or used in the detailed description of the present invention.

For reference, a part irrelevant to the description will be omitted for clarity of the present invention. In the following description, the same or similar elements will be designated by the same reference numerals through the entire specification. Although the elements and their shapes are simplified or exaggerated in the drawings to help understanding of the present invention, the same reference numerals are used to designate the same or similar components.

Also, when it is described that a layer or an element is located “above” or “on” another layer or element, it means not only that the layer or element may be disposed so as to directly contact another layer or element but also that a third layer may be interposed between them.

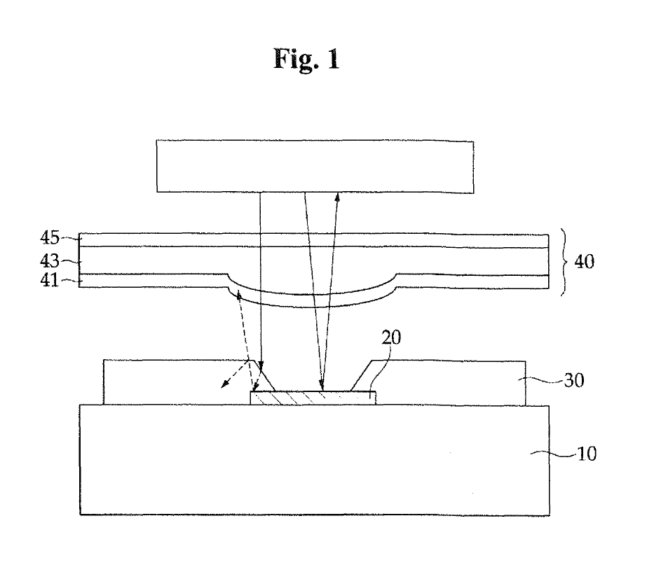

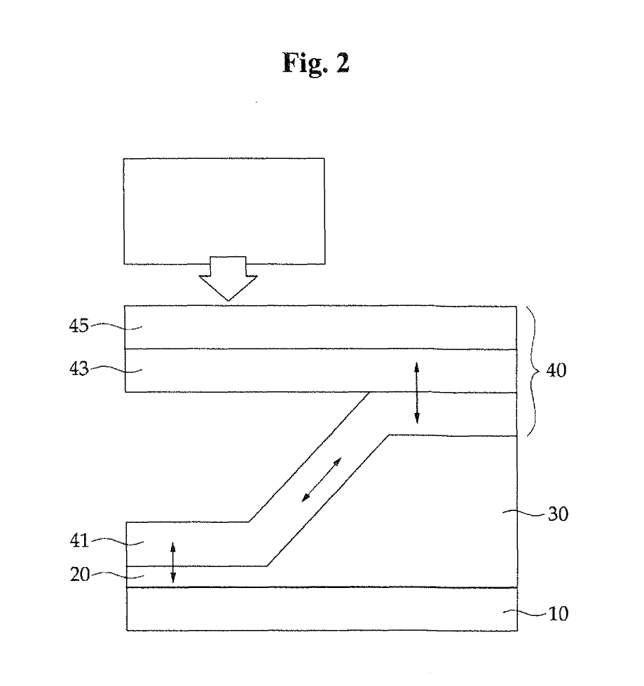

FIG. 1 schematically illustrates a method of forming a light emitting layer by LITI, and FIG. 2 is a view illustrating an example of a non-transfer defect generated due to the continuous application of a force between a region that has been irradiated by the laser and a region that has not been irradiated by the laser when a transfer is performed.

Referring to FIG. 1, a thermal imaging donor film 40 includes a base layer 45, a light to heat conversion layer 43, and a transfer layer 41, which are flatly laminated on a flat substrate. When a red color, a green color, and a blue color are applied on the donor film 40 and then the laser is irradiated onto the donor film 40, the light to heat conversion layer 43 of the donor film 40 absorbs the laser so as to generate heat. The generated heat expands the donor film 40, causing the transfer layer 41 to be transferred to the substrate.

However, as illustrated in FIG. 2, when a transfer is performed through an irradiation of the laser in a state in which a donor film is aligned with a pixel part, an open edge defect may be generated, in which a portion in an edge part may not be transferred due to a continuous application of a force between a portion that has been irradiated by the laser and a portion that has not been irradiated by the laser.

Accordingly, technology capable of preventing the open edge defect generated due to the failure of appropriate contact between an end of the anode and the light emitting layer when the light emitting layer is patterned through the LITI is required.

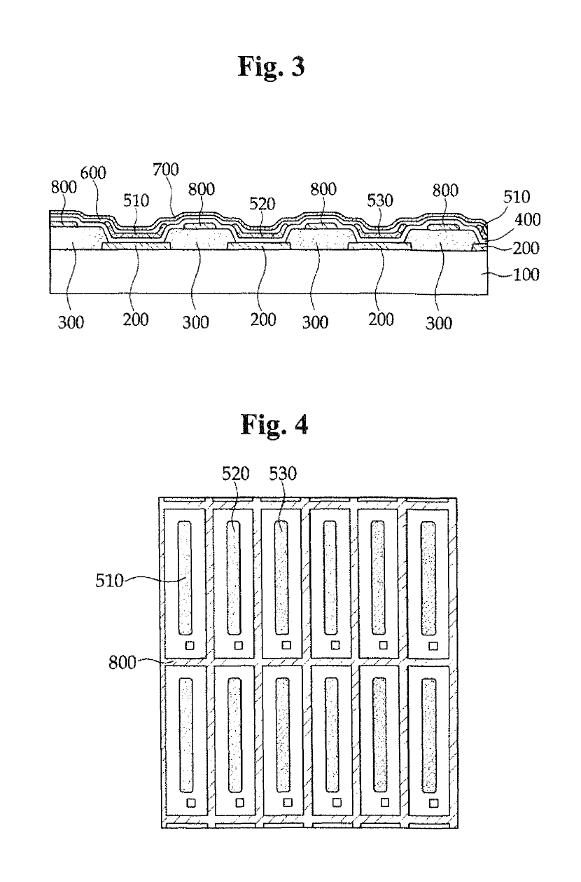

FIG. 3 is a view illustrating an organic light emitting device according to an embodiment of the present invention.

Referring to FIG. 3, the organic light emitting device includes a base 100, first electrodes 200 patterned and formed on the base 100, pixel definition layers 300 formed between the patterned first electrodes 200, reflective layers 800 formed on the Pixel definition layers, light emitting layers 510, 520, and 530 formed on upper portions of the first electrodes, and a second electrode 700 formed on the upper portions of the light emitting layers. Furthermore, the organic light emitting device illustrated in FIG. 3 includes a first auxiliary light emitting layer 400 formed between the light emitting layers 510, 520 and 530 and the first electrode 200 and a second auxiliary light emitting layer 600 formed between the light emitting layers 510, 520 and 530 and the second electrode 700.

The light emitting layers, the first auxiliary light emitting layer, and the second auxiliary light emitting layer correspond to organic layers.

As illustrated in FIG. 3, the first electrodes 200 may be classified in units of pixels by the pixel definition layers 300, and the light emitting layers 510, 520 and 530 are formed on the upper portions of the first electrode layers 200 classified in the units of pixels by the pixel definition layers 300. Here, the first electrode corresponds to a pixel electrode.

The light emitting layers 510, 520 and 530 are the red light emitting layer 510, the green light emitting layer 520, and the blue light emitting layer 530. The light emitting layers are made of a red light emitting material, a green light emitting material, and a blue light emitting material, respectively, and the light emitting layers are organic materials. The light emitting material may be selected from those used in the art to which the present invention pertains.

It can be seen from FIG. 3 that the first auxiliary light emitting layer 400 is formed on an entire upper surface of the patterned first electrodes 200, the reflective layers 800, and the pixel definition layers 300.

The first auxiliary light emitting layer 400 may be a hole injection layer or a hole transport layer. The first auxiliary light emitting layer 400 may include two layers, including both a hole injection layer and a hole transport layer separately.

It is illustrated in the embodiment of FIG. 3 that the first auxiliary light emitting layer 400 is a hole injection and transport layer having both a hole injection function and a hole transport function.

Furthermore, referring to FIG. 3, the second auxiliary light emitting layer 600 is formed on entire upper surfaces of the light emitting layers 510, 520, and 530 and the first auxiliary light emitting layer 400. The second auxiliary light emitting layer 600 may be an electron injection layer or an electron transport layer. It is apparent that the second auxiliary light emitting layer 600 may include two layers, and may include both the electron injection layer and the electron transport layer separately.

It is illustrated in the embodiment of FIG. 3 that the second auxiliary light emitting layer 600 is an electron transport layer.

In the embodiment of FIG. 3, the first electrodes 200 are anodes serving as pixel electrodes and the second electrode 700 is a cathode serving as a common electrode.

The first electrodes 200 serving as anodes am formed on the base 100 in a pattern form. The first electrodes 200 serving as pixel electrodes supply electric charges to the red light emitting layer 510, the green light emitting layer 520, and the blue light emitting layer 530, respectively. The red light emitting layer 510, the green light emitting layer 520, and the blue light emitting layer 530 formed on the upper portions of the first electrodes 200 become a red pixel, a green pixel, and a blue pixel, respectively.

Furthermore, the second electrode 700, i.e. the cathode, is formed on an entire upper surface of the second auxiliary light emitting layer 600.

FIG. 4 is a view illustrating exemplary planar dispositions of reflective layers in an organic light emitting device according to the present invention.

As illustrated in FIG. 4, the reflective layers 800 may be formed in the form of a mesh between the light emitting layers. In addition, the reflective layers 800 may be formed in the form of lines or a comb.

As illustrated in FIG. 3, the reflective layers 800 are formed on the pixel definition layers 300.

The pixel definition layers 300 are formed of an insulating material. The material of the pixel definition layers 300 may be selected from those used in the art to which the present invention pertains.

The pixel definition layers 300 are generally formed between the first electrodes 200 so as to classify the first electrodes 200 in units of pixels.

The first auxiliary light emitting layer 400 is disposed on the upper portions of the reflective layers 800, and the first auxiliary light emitting layer 400 is formed on an entire upper surface of the first electrodes 200, the reflective layers 800, and the pixel definition layers 300.

The reflective layers 800 are formed on the pixel definition layers 300, and it is general that the reflective layers 800 are formed after the first electrodes 200 and the pixel definition layers 300 are formed. Accordingly, it is especially preferable to select a material capable of minimizing damage to the first electrodes 200 during the forming of the reflective layers 800.

The reflective layers 800 may be a single layer or a plurality of stacked layers. The reflective layers 800 may include a metal layer.

The reflective layers 800 are patterned on the pixel definition layers 300, and a method of patterning the reflective layers formed of the metal layers includes a PhotoResist (PR) process and an etching process. The etching process uses an etching solution, and some of the etching solution may damage the first electrodes 200. Accordingly, when an etching process is included for forming the reflective layers (metal layers), the reflective layers should be formed of metal capable of minimizing the damage to the first electrodes 200 during the etching process.

In the present embodiment, the first electrodes include a Transparent Conductive Oxide (TCO) layer. The TCO layer may be selected from those generally used in the art to which the present invention pertains, and for example, may be an ITO layer, an IZO layer, and an AZO layer. In the present embodiment, the first electrodes are formed of the ITO layer.

In this case, in order to minimize damage to the first electrodes, the first electrodes formed of the ITO may be cured before the forming of the reflective layers.

Considering these facts, the reflective layers 800 may, for example, be made of any one of molybdenum (Mo), silver (Ag), chrome (Cr), titanium (Ti), ytterbium (Yb), gold (Au), copper (Cu), and aluminum (Al). That is, the reflective layers 800 may include at least one of a molybdenum (Mo) layer, a silver (Ag) layer, a chrome (Cr) layer, a titanium (Ti) layer, a ytterbium (Yb) layer, a gold (Au) layer, a copper (Cu) layer, and an aluminum (Al) layer. The reflective layers 800 may include a layer made of another metal in addition to the aforementioned metal layer, and may have a plurality of stacked metal layers.

For example, the reflective layers 800 may be made of molybdenum (Mo). In the etching process among the processes for the patterning of molybdenum (Mo), an etching solution including nitric acid, phosphoric acid, and acetic acid is used. In this case, the etching solution does not greatly corrode the cured ITO electrodes.

According to an example of the present invention, the base 100 may include a substrate, a thin film transistor (TFT) layer, and a flat insulation layer. The base 100 may be only a substrate. Accordingly, the base 100 may occasionally have the same meaning as a substrate.

For simplicity, FIG. 3 does not illustrate the individual elements of the base 100.

Hereinafter, a method of manufacturing the organic light emitting device according to the present invention will be described with reference to the structure of the organic light emitting device illustrated in FIG. 3.

A base 100 is prepared first, and a material for forming fast electrodes is applied to the base 100.

The process of preparing the base 100 may include a step of preparing a substrate, a step of forming a TFT layer, and a step of forming a flat insulation layer. In the embodiment of the present invention, descriptions of the processes will be entirely omitted. Meanwhile, the base may be only a substrate.

A method generally used in the art to which the present invention pertains may be applied as a method of applying the material for forming the first electrodes. It is apparent that an example of such a method includes a sputtering method and a method other than the sputtering method may be applied.

The first electrodes 200 may include at least one of a transparent conductive oxide (TCO) layer and a metal layer. Accordingly, the process of applying the material for forming the first electrodes 200 may include at least one of a step of forming the transparent conductive oxide (TCO) layer and a step of forming the metal layer. In this regard, the transparent conductive oxide (TCO) layer may include at least one of an ITO layer, an IZO layer, and an AZO layer. The metal layer may include at least one of a silver (Ag) layer, a molybdenum (Mo) layer, a chrome (Cr) layer, and an aluminum layer (Al).

Meanwhile, the first electrodes 200 may have a structure wherein an ITO layer, a silver (Ag) layer, and an ITO layer are sequentially stacked. In order to form the first electrodes 200 where the ITO layer, the silver (Ag) layer, and the ITO layer are sequentially stacked, a step of forming the ITO layer, a step of forming the silver (Ag) layer, and a step of forming the ITO layer are sequentially performed.

In the present embodiment, the forming of the first electrodes of the ITO layer will be described as an example.

The first electrodes 200 are formed by patterning the material for forming the first electrodes, which is applied to the base 100. A method generally used in the art to which the present invention pertains may be applied to the patterning method.

A pixel definition layer forming material is applied to entire upper surfaces of the patterned first electrodes 200 and the base 100. The pixel definition layer forming material may be an electrically insulating material, and a material generally used in the art to which the present invention pertains may be appropriately selected and used as the material.

The pixel definition layers 300 are formed by patterning the pixel definition layer forming material.

A method generally used in the art to which the present invention pertains may also be applied to the method of patterning the pixel definition layers 300.

Reflective layers 800 are formed on the pixel definition layers 300.

It is general to form the reflective layer 800 after the first electrodes 200 and the pixel definition layers 300 are formed.

The reflective layers 800 may be a single layer or a plurality of stacked layers.

For example, the reflective layers 800 may be formed by applying the reflective layer forming material to the upper surfaces of the pixel definition layers in a single layer or multiple layers, and then patterning the reflective layer forming material. Otherwise, the reflective layers 800 may be formed by stacking the reflective layer forming material on the entire upper surfaces of the pixel definition layers and the first electrodes in a single layer or multiple layers, and then patterning the reflective layer forming material.

The first electrodes 200 and the pixel definition layers 300 may be damaged during the process of forming the reflective layers 800 described above. Especially, the first electrodes 200 and the pixel definition layers 300 may be damaged during the patterning process.

Particularly, a method of patterning the reflective layers 800 on the pixel definition layers 300 includes a PhotoResist (PR) process and an etching process. The etching process uses an etching solution, and some of the etching solution may damage the first electrodes 200 and the pixel definition layers 300. Accordingly, when the etching process is included for forming the reflective layers 800, the reflective layers 800 should be formed of a material capable of minimizing the damage to the first electrodes 200 and the pixel definition layers 300 during the etching process.

In particular, damage to the first electrodes directly affects the light emitting efficiency of the organic light emitting device. Accordingly, it is preferable to select a material for forming the reflective layers 800 which is capable of most effectively minimizing the damage to the first electrodes 200.

The reflective layers according to the present invention include a metal layer. In order to minimize the damage to the first electrodes during the patterning of the reflective layers including the metal layers, the first electrodes may be cured before the forming of the reflective layers.

In the present embodiment, the forming of the first electrodes using ITO among the transparent conductive oxides will be described as an example. Accordingly, in the present embodiment, the method may further include a step of curing the first electrodes made of ITO before the step of forming the reflective layers 800.

Particularly, the reflective layers 800 may, for example, be made of any one of molybdenum (Mo), silver (Ag), chrome (Cr), titanium (Ti), ytterbium (Yb), gold (Au), copper (Cu), and aluminum (Al). In the etching process during the process of patterning molybdenum (Mo), silver (Ag), chrome (Cr), titanium (Ti), ytterbium (Yb), gold (Au), copper (Cu), or aluminum (Al), an etching solution including nitric acid, phosphoric acid, and acetic acid is used. In this case, the etching solution does not greatly corrode the cured ITO electrodes.

The reflective layers 800 include a layer made of another metal in addition to the metal layer, and may have a plurality of stacked metal layers.

In the embodiment, the forming of the reflective layers 800 of molybdenum (Mo) will be described as an example. By adjusting a composition of the etching solution used in the etching process of the molybdenum (Mo), it is possible to minimize corrosion of the cured ITO electrodes.

In the patterning of the reflective layers 800, the reflective layers 800 may be formed in any one of a mesh, lines, and a comb between the light emitting layers.

Furthermore, a gap between the first electrode 200 and the reflective layer 800 is preferably at least 4 μm, but a gap smaller or larger than 4 μm is accepted. An area of the reflective layer 800 may be 50% to 100% of an upper area of the pixel definition layer 300.

In the method according to the embodiment of the present invention, before the light emitting layers 510, 520, and 530 are formed, a first auxiliary light emitting layer 400 is formed.

It can be seen that the first auxiliary light emitting layer 400 is formed on entire surfaces of the first electrodes 200, the reflective layers 800, and the pixel definition layers 300.

The first auxiliary light emitting layer 400 may be any one of a hole injection layer and a hole transport layer, but may include both a hole injection layer and a hole transport layer.

For reference, the step of forming the first auxiliary light emitting layer 400 may include at least one of forming a hole injection layer and forming a hole transport layer, but may also include both steps.

For example, when the first auxiliary light emitting layer 400 includes two layers, the hole injection layer may be formed first and the hole transport layer may be formed later.

Thereafter, the light emitting layers 510, 520, and 530 are formed on the first auxiliary light emitting layer 400.

The light emitting layers 510, 520, and 530 are located on the first electrodes 200 classified in units of pixels by the pixel definition layers 300. The light emitting layers 510, 520, and 530 are the red light emitting layer 510, the green light emitting layer 520, and the blue light emitting layer 530. The light emitting layers may be formed by a method generally used in the art to which the present invention pertains so that a detailed description of the method of forming the light emitting layers will be omitted.

Meanwhile, in the process according to the embodiment of the present invention, a second auxiliary light emitting layer 600 is formed after the light emitting layers 510, 520, and 530 are formed and before the second electrode 700 is formed.

The second auxiliary light emitting layer 600 is formed on an entire upper surface of the light emitting layers 510, 520, and 530 and the first ancillary light emitting layer 400.

The second auxiliary light emitting layer 600 may include at least one of an electron injection layer and an electron transport layer. Accordingly, the step of forming the second auxiliary light emitting layer 600 may include at least one of forming the electron injection layer and forming the electron transport layer.

In the embodiment of the present invention, it is illustrated that the second auxiliary light emitting layer 600 is an electron transport layer. Accordingly, the electron transport layer is formed as the second auxiliary light emitting layer 600.

It is a matter of course that the second auxiliary light emitting layer 600 may include two layers, and may include both an electron injection layer and an electron transport layer separately.

Next, a second electrode 700 is formed on the second auxiliary light emitting layer 600. The second electrode 700 is formed on an entire upper surface of the second auxiliary light emitting layer 600.

The organic light emitting device according to the present invention may be manufactured by the above-described process.

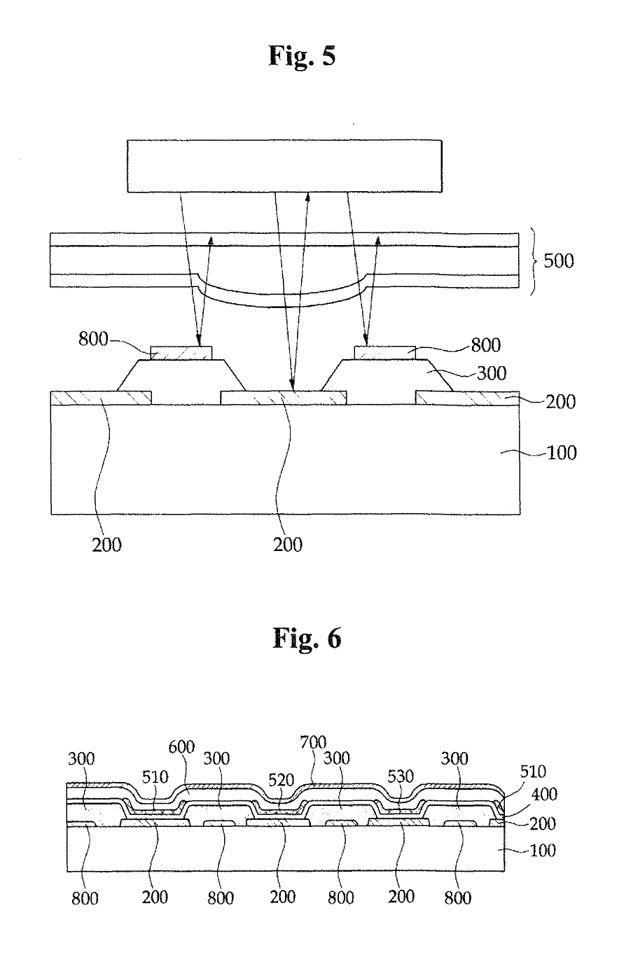

FIG. 5 is a view illustrating a transfer process of an organic light emitting device according to an embodiment of the present invention. More specifically, the organic light emitting device is manufactured by the aforementioned process including LITI according to an embodiment of the present invention.

In the organic light emitting device manufactured according to an embodiment of the present invention, a force, i.e. cohesive force, existing between a region that has been irradiated by the laser and a region that has not been irradiated by the laser at the edge portion during the irradiation of the laser, is decreased, making it possible to easily progress the transfer and remove a non-transfer defect.

Particularly, when the laser is irradiated during the transfer, the donor film 500 absorbs the laser and generates heat, so that the donor film 500 is expanded. Simultaneously, a larger amount of heat is generated at the edge portion by the laser reflected through the reflective layers 800 so that the edge portion is further expanded compared to other portions. Accordingly, the cohesive force in the edge portion is decreased and the transfer at the edge portion is easily progressed, thereby preventing the generation of the non-transfer defect.

FIG. 6 is a view illustrating an organic light emitting device according to another embodiment of the present invention.

According to the present invention, when a gap between the pixel definition layers 300 is large, for example, when a gap between the pixel definition layers 300 is equal to or larger than 17 μm, the reflective layers 800 and the first electrodes 200 may be simultaneously deposited on the same base 100. An example of the organic light emitting device manufactured as described above is illustrated in FIG. 6.

Another example of the present invention provides an organic light emitting device illustrated in FIG. 6 including: a base 100; first electrodes 200 patterned and formed on the base 100; pixel definition layers 300 formed between the patterned first electrodes 200; reflective layers 800 formed on the base to cover outside portions of the reflective layers 800 by the pixel definition layers 300; one or more first auxiliary light emitting layers 400 formed on the pixel definition layers 300; light emitting layers 510, 520, and 530 formed on the first auxiliary light emitting layer 400; one or more second auxiliary light emitting layers 600 formed on the light emitting layers 510, 520, and 530; and a second electrode 700 formed on the second auxiliary light emitting layer 600. The pixel definition layers 300 have an optical permeability, and the light emitting layers 510, 520, and 530 are formed on upper portions of the patterned first electrodes 200 classified in units of pixels.

In this case, the first auxiliary light emitting layer 400 may include at least one of a hole injection layer and a hole transport layer. The second auxiliary light emitting layer 600 may include at least one of an electron injection layer and an electron transport layer.

In the present embodiment, the first electrode 200 is an anode and the second electrode 700 is a cathode.

Furthermore, a gap between the first electrode 200 and the reflective layer 800 is preferably at least 4 μm, but a gap smaller or larger than 4 μm is accepted. An area of the reflective layer 800 may be 50% to 90% of a lower area of the pixel definition layer 300, and the pixel definition layer 300 covers the outside portion of the reflective layer 800.

Another example of the present invention provides a method of manufacturing an organic light emitting device, the method including the steps of: preparing a base; forming first electrode patterns on the base; forming reflective layers on the base between the first electrode patterns; forming pixel definition layers so as to cover outside portions of the reflective layers; forming one or more first auxiliary light emitting layers on the first electrode patterns and the pixel definition layers; forming light emitting layers on the first auxiliary light emitting layer; forming one or more second auxiliary light emitting layers on the light emitting layers; and forming a second electrode on the second auxiliary light emitting layer. The pixel definition layers have an optical permeability, and the light emitting layers are formed on the first electrodes patterns classified in units of pixels.

In this regard, the step of forming the reflective layers is performed before the step of forming the pixel definition layers, and the pixel definition layers are framed on the reflective layers.

In the present embodiment, the step of forming the first auxiliary light emitting layer may include at least one of forming a hole injection layer and forming a hole transport layer. Furthermore, the step of forming the second auxiliary light emitting layer may include at least one of forming an electron injection layer and forming an electron transport layer.

In the present embodiment, the first electrode is an anode and the second electrode is a cathode.

The organic light emitting device according to another embodiment of the present invention may be manufactured through the above-described process.

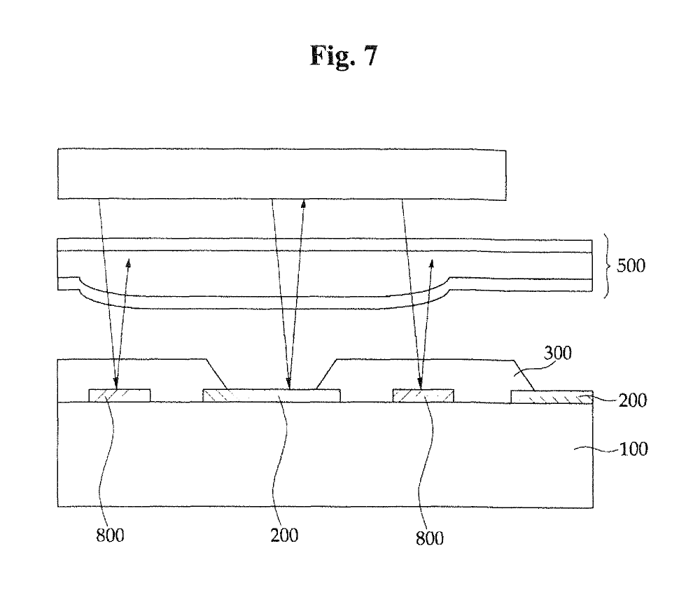

FIG. 7 is a view illustrating a transfer process of an organic light emitting device according to another embodiment of the present invention, and more specifically an organic light emitting device manufactured through the aforementioned process by LITI.

In the organic light emitting device manufactured according to another embodiment of the present invention, a force, i.e. cohesive force, existing between a region that has been irradiated by the laser and a region that has not been irradiated by the laser at the edge portion during the irradiation of the laser, is decreased, making it possible to easily progress the transfer and remove a non-transfer defect.

Particularly, when the laser is irradiated during the transfer, the donor film 500 absorbs the laser and generates heat so that the donor film 500 is expanded. Simultaneously, a larger amount of heat is generated at the edge portion by the laser reflected through the reflective layer 800, so that the edge portion is further expanded compared to other portions. Accordingly, the cohesive force in the edge portion is decreased and the transfer at the edge portion is easily progressed, thereby preventing the non-transfer defect from being generated.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An organic light emitting device, comprising:
a base;
first electrodes patterned and formed on the base;
light emitting layers formed on the first electrodes; and
a second electrode formed on the light emitting layers;
wherein pixel definition layers (PDLs) are formed between the patterned first electrodes, and reflective layers are disposed in the pixel definition layers.

2. The organic light emitting device as claimed in claim 1, wherein each said reflective layer is formed on an upper portion of one of the pixel definition layers.

3. The organic light emitting device as claimed in claim 1, wherein each said reflective layer is formed on an inner side of one of the pixel definition layers.

4. The organic light emitting device as claimed in claim 3, wherein each said reflective layer is formed on a substrate.

5. The organic light emitting device as claimed in claim 3, wherein each said pixel definition layer has an optical permeability.

6. The organic light emitting device as claimed in claim 3, wherein an area of each said reflective layer is 50% to 90% of an area of a lower portion of one of the pixel definition layers, and each said pixel definition layer covers an outside portion of one of the reflective layers.

7. The organic light emitting device as claimed in claim 2, wherein an area of each said reflective layer is 50% to 100% of an area of an upper portion of one of the pixel definition layers.

8. The organic light emitting device as claimed in claim 1, further comprising at least one of a hole injection layer and a hole transport layer disposed between one of the light emitting layers and one of the first electrodes.

9. The organic light emitting device as claimed in claim 1, further comprising at least one of an electron injection layer and an electron transport layer disposed between one of the light emitting layers and a second electrode.

10. The organic light emitting device as claimed in claim 1, wherein the first electrodes are pixel electrodes.

11. The organic light emitting device as claimed in claim 1, wherein the first electrodes are anodes and the second electrodes are cathodes.

12. The organic light emitting device as claimed in claim 1, wherein each said reflective layer includes a metal layer.

13. The organic light emitting device as claimed in claim 12, further comprising at least one insulation layer formed on the metal layer.

14. The organic light emitting device as claimed in claim 13, wherein said at least one insulation layer has an optical permeability.

15. The organic light emitting device as claimed in claim 12, wherein the metal layer includes at least one of a molybdenum (Mo) layer, a gold (Au) layer, a silver (Ag) layer, a chrome (Cr) layer, a titanium (Ti) layer, a ytterbium (Yb) layer, a copper (Cu) layer, and an aluminum (Al) layer.

16. The organic light emitting device as claimed in claim 1, wherein the reflective layers are formed in any one of a mesh, lines, and a comb.

17. The organic light emitting device as claimed in claim 1, wherein the base includes a substrate, a thin film transistor (TFT) layer, and a flat insulation layer.

18. The organic light emitting device as claimed in claim 1, wherein the base includes a substrate.

19. A method of manufacturing an organic light emitting device, the method comprising the steps of:
preparing a base;
forming patterns of first electrodes on the base;
forming pixel definition layers between the first electrodes such that the first electrodes are classified in units of pixels;
forming light emitting layers on the first electrodes classified in units of pixels; and
forming a second electrode on the light emitting layers;
said method further comprising a step of forming reflective layers at a time different from the time that the step of forming the pixel definition layers is performed.

20. The method as claimed in claim 19, wherein the step of forming the reflective layers is performed after the step of forming the pixel definition layers is performed, and the reflective layers are formed on the pixel definition layers.

21. The method as claimed in claim 19, wherein the step of forming the reflective layers is performed before the step of forming the pixel definition layers is performed, and the pixel definition layers are formed on the reflective layers.

22. The method as claimed in claim 19, further comprising at least one of a step of forming a hole injection layer and a step of forming a hole transport layer after the step of forming the pixel definition layers is performed and before the step of forming the light emitting layers is performed.

23. The method as claimed in claim 19, further comprising at least one of a step of forming an electron transport layer and a step of forming an electron injection layer after the step of forming the light emitting layers is performed and before the step of forming the second electrode is performed.

24. The method as claimed in claim 19, wherein the step of forming the reflective layers is simultaneously performed with the step of forming the patterns of the first electrodes.

25. The method as claimed in claim 19, wherein the step of forming the reflective layers includes a step of forming metal layers.

26. The method as claimed in claim 25, wherein the metal layers include at least one of a molybdenum (Mo) layer, a gold (Au) layer, a silver (Ag) layer, a chrome (Cr) layer, a titanium (Ti) layer, a ytterbium (Yb) layer, a copper (Cu) layer, and an aluminum (Al) layer.

27. The method as claimed in claim 19, wherein in the step of forming the reflective layers, the reflective layers are formed in any one of a mesh, lines, and a comb.
